(19) United States
(12) Patent Application Publication
(10) Pub. No.: US 2012/0125409 A1
(43) Pub. Date: May 24, 2012

(54) FASTENING OF PANEL-TYPE ELEMENTS

(75) Inventors: Werner BELSCHNER, Michelbach a.d. Bilz (DE); Matthias BARIE, Kupferzell (DE); Timo HANSELMANN, Schrozberg (DE)

(73) Assignee: WUERTH SOLAR GMBH & CO. KG, Schwaebisch Hall (DE)

(21) Appl. No.: 13/298,392

(22) Filed: Nov. 17, 2011

(30) Foreign Application Priority Data
Nov. 17, 2010 (DE) 10 2010 051 468.3

(51) Int. Cl. H01L 31/048; H01L 23/12

(52) U.S. Cl. 136/251; 211/41.1

(57) ABSTRACT

A mounting system for panel-type elements, in particular facade elements, thermoelectric generator elements, thermal solar collectors, photovoltaic modules or solar modules is described, for fastening and securing the element on at least one upper and one lower transverse rail, which are arranged in parallel with and at a spacing from each other for holding an element. The mounting system includes: at least one fastening member fixedly connected to the back side of the element and having at least one anchoring member arranged substantially perpendicularly to the back side for fastening to the upper transverse rail. In the installed position of the element, the fastening member has a smaller distance, relative to a line of slope, from an upper edge of an outer contour of the element than from a lower edge of the outer contour. A panel-type element including a like mounting system, as well as a substructure for holding such an element are also described.

### CROSS-REFERENCE TO RELATED APPLICATIONS

The present application claims priority from German Application DE 10 2010 051 468.3, filed on Nov. 17, 2010.

### FIELD OF THE INVENTION

The invention relates to a mounting system for panel-type elements in general and for facade elements, thermoelectric generator elements, thermal solar collectors, photovoltaic modules or solar modules in particular, for fastening such an element on at least one upper and one lower transverse rail which are arranged in parallel with and at a spacing from one another for holding such a panel-type element. The invention further relates to a panel-type element comprising a like mounting system, as well as a substructure for holding such an element.

### BACKGROUND

Numerous systems for panel-type solar modules or photovoltaic (PV) modules are known for the direct fastening or indirect fastening via a substructure or supporting structure for PV modules mounted on stands on facades or roofs of buildings or in open terrain.

DE 10 2008 052 594 A1 shows a multi-part holding system for fastening panel-type solar modules to four respective peripheral points by means of a retainer of a clamping device. The clamping device comprises an upper U-shaped mount having a mouth-shaped opening for an upper module and a U-shaped mount having a mouth-shaped opening for a lower module, with these mounts being arranged vertically and the openings being oriented away from each other. The clamping device is mounted on the building by means of a fastening section with the aid of a central screw, with the upper mount and/or the lower mount being adapted for being pivoted and locked relative to this fastening section. Here it is a drawback that the holding system is made up of numerous mounting parts, with mounting accordingly being highly time-consuming. Critical stresses may moreover occur in the modules when loaded, due to being clamped at four points.

DE 10 2009 024 615 A1 shows a mounting system for PV modules having at least two profile-type transverse rails which are arranged in parallel with and at a spacing from one another and provided for holding several PV modules, each of which has a planar support surface. Retainers are fixedly connected to the back side of a PV module by means of an adhesion agent, with the PV module being adapted to be hung on the transverse rails by means of the retainers. To this end at least one retainer is associated to each transverse rail, with each retainer having a depression and each transverse rail having an integrated projection, or vice versa. In order to hang the PV module, it is first of all placed on the transverse rails such that the retainers planarly rest on the support surfaces of the transverse rails and are then displaced, while resting on the latter, in a joining direction perpendicular to the transverse rails, with the depressions and the projections engaging each other. Between at least one transverse rail and a retainer associated to it a holding interlock is provided which prevents a displacement of the retainer against the joining direction. Here it is a drawback that the retainer is very complex in order to realize a tolerance compensation with regard to the spacing of the transverse rails and also in order to secure the PV module against theft or wind suction.

From DE 10 1008 032 985 A1 a fastening structure for a large-surface solar module is known. The fastening structure comprises a substructure having two reception profiles which cooperate with retainer profiles for fastening the solar module. These reception and retainer profiles form a locking engagement.

From DE 20 2010 007 658 U1 a module carrier is known, in particular for photovoltaic modules, which is to be set up on flat roofs. The module carrier comprises front and rear retainer profiles having mounts for the profiles as well as a wind sealing member.

From FR 2 538 867 A1 a retaining device for fastening wall cladding panels to a vertical wall is known.

From FR 2 928 672 A1 a facade cladding, in particular for a facade or a roof, is known.

Lastly, from WO 99 017 063 A1 a fastening for solar modules is known, comprised of at least one reception part for fastening on site, and fastening means for fastening a solar module to this reception part. The fastening means are projections, pins, hooks or the like, which are connected to the solar module or molded on the latter.

It would therefore be desirable to provide a mounting system for panel-type elements, in particular for facade elements, thermoelectric generator elements, thermal solar collectors, solar modules or photovoltaic modules, for fastening such elements to facades or roofs of buildings or to a supporting structure, which mounting system is simple in its construction and involves less mounting complexity than previously known mounting systems.

### SUMMARY

A mounting system in accordance with embodiments of the invention serves for fastening, and in a given case securing panel-type elements, in particular facade elements, thermoelectric generator elements, thermal solar collectors, photovoltaic modules or solar modules, to at least one upper and one lower transverse rail which are arranged in parallel with and at a spacing from one another for holding the element.

In this context it should be noted that “panel-type” means such an element to have a clearly lower thickness as compared with its length and width, i.e. it substantially has the shape of a panel. The outer contour of the panel-type elements is usually rectangular or even square but may fundamentally present any desired shape.

The mounting system comprises at least one fastening member fixedly connected to a back side of the panel-type element, which comprises at least one anchor which is preferably arranged substantially perpendicularly to the plane of the back side for fastening to the upper transverse rail. In the installed position of the element the fastening member is arranged, relative to a line of slope, at a lower distance from an upper edge of an outer contour of the element than from a lower edge of the outer contour.

By means of a securing member the lower supporting location of the element is secured against the bearing direction. Via the dimensioning of the mouth opening width of the mouth-shaped opening and with intermediate arrangement of an elastic material it is possible to better secure the element against unauthorized removal and in particular against wind lift and accompanying flutter of the element. Moreover this serves to protect the fastening locations at the upper supporting locations, i.e. the double bearing, on the element against moment loads.

In its cross-section the elastic member may be configured to be triangular, oval, circular or quadrangular, for instance. The plane of the cross-section extends transversely, in particular at a right angle, relative to the surface plane of the panel-type elements. Moreover the plane of the cross-section may extend in such a way that the line of slope is contained in this cross-sectional plane. This allows to produce the elastic member by cutting lengths of continuous material which is present in the form of an endless product.

The elastic member may be made of a soft rubber, silicone, or ethylene propylene diene monomer rubber (EPDM). Soft rubber is a material which is particularly low-cost and easy to work. Silicone or ethylene propylene diene monomer rubber (EPDM) are particularly well suited because both materials are particularly UV-resistant. Moreover, silicone or ethylene propylene diene monomer rubber (EPDM) are particularly resistant to chemicals, in particular to ammonia-containing gases as may be present at elevated concentrations in the vicinity of agricultural buildings for livestock production.

The elastic member may be fastened integrally to the PV module or to a substructure. If the elastic member consists of silicone, the silicone may be sprayed onto the PV module and thus provided with the desired shape. It is, however, also possible to use a pre-fabricated elastic member, e.g. of ethylene propylene diene monomer rubber (EPDM), which is bonded to a PV module for producing this integral connection.

Various embodiments of the invention provide a particularly simple fastening of the panel-type element by means of a double bearing, in the form of a bearing comprising an anchor which is immobilized in a fitting reception, e.g. by form-fit or optionally also by an adhesion agent. The fastening of the entire element to the substructure is predominantly achieved through the anchoring member, so that it may be mounted in a very simple, fast and yet secure manner.

In one advantageous development of the mounting system there is further provided at least one securing member which, in the installed position of the element, is arranged below the fastening member relative to the line of slope. The securing member is adapted such that in the installed position of the element it restricts—or with corresponding dimensioning entirely prevents—the freedom of movement of the element perpendicularly to the mounting plane away from the substructure.

The gist of the advantageous development resides in the realization of the fastening of the panel-type element through a combination of a movable (simple) bearing having the form of a simple support, with the double bearing having the form of the support comprising the anchoring member. The fastening of the entire element to the substructure is furthermore effected predominantly through the anchoring member and may therefore be mounted in a very simple, fast and yet secure manner. As a result of the presently proposed development of the mounting system comprising a movable bearing half, stresses within the element such as, e.g., a sheet of glass or silicon layer of the element due to mechanical and/or thermal loads are minimized or prevented.

To this end, the securing member may have an angled arm which extends at a spacing from and in parallel with the back side of the element and substantially perpendicularly to the line of slope. Together with the back side, the arm forms a mouth-shaped opening opened substantially in the direction of the line of slope so as to reach around an undercut formed on or by the lower transverse rail when viewed from the mounting plane.

As regards the fastening of the at least one fastening member and in a given case of the at least one securing member to the back side of the panel-type element, the following should be noted.

Both a fastening member and a securing member possess a fastening surface for fastening to the back side of the element, for example a planar contact surface of a foot plate of the element. The fastening surface may then be bonded with the back side of the element by means of an adhesive bond.

The kind of the adhesive suited for the adhesive bond is essentially determined by the materials to be connected. If the fastening members and in a given case the securing members consist of a metal, then a silicone-based adhesive is particularly well suited, for instance for bonding with the glass back side of a PV module as a panel-type element. Such a PV module might have a layer of plastic laminated on the back side, for example for improved protection of the glass substrate. In this case, if the fastening members and in a given case the securing members equally consist of a plastic material, it is also possible to use integral fastening such as, e.g., by ultrasonic welding or friction welding, for fastening. Alternatively it is also always possible to use a carrier coated on either side with a respective suitable adhesive in the manner of a two-sided adhesive tape.

It should moreover be noted that particularly due to the high value of thermoelectric generator elements, thermal solar collectors, PV modules or solar modules, these present a particularly high incentive for theft, particularly in facilities that are supported on the ground and arranged on a roof in remote areas such as, for example, in industrial areas or in open-field installations. In order to minimize the incentive to thieves, the fastening at least of the fastening members on the back side of such panel-type elements may be realized such that these can only be removed from the element by concurrently destroying the latter. If the anchoring member is adapted such as to enter a non-releasable connection in the connection to a substructure, which is adapted to be stronger than the force required for destroying the element at the fastening locations, the element will be destroyed in the course of an attempted theft and therefore useless, hence worthless.

Furthermore at least one elastic member such as, e.g., a silicone rubber strip is arranged, relative to the line of slope, below the at least one fastening means on the back side of the element such that the elastic member rests on the lower transverse rail when an element is mounted on the transverse rails, i.e. in the installed position thereof. Damage to the element due to the contact with the transverse rail having a higher rigidity in comparison with the element is hereby avoided.

A plurality of fastening members and in a given case a plurality of securing members may be arranged on the back side of the element on a line extending substantially perpendicularly to the line of slope. In a preferred manner, one respective fastening member and one respective securing member are also arranged on the back side of the element on a line extending substantially in parallel with the line of slope. Here it should, however, be noted that a lateral offset between a fastening member and a securing member arranged below it does not impair the function of the fastening system.

The fastening member and/or the securing member may also be realized as a profile rail each fastened to the back side of the element substantially perpendicularly to the line of slope. The anchoring member as well as the angled arm of the securing member may then also be realized in a corresponding web shape and cooperate with the respective transverse rails in accordance with their purpose of use.

The at least one fastening member or the at least one elastic member may each be arranged inside the surface area of the back side at a distance from the outer contour of the element. The fastening locations of the fastening members and the supporting locations of the element at the lower transverse rail may be selected such that the bearing points resulting in such locations for the element in the installed position that the element is subjected to a minimum flexural load in the installed position. The fastening locations on the back side of the element may be selected such as to result, in the event of an elastic deformation of the element due to surface load due, e.g., to wind or snow, in horizontal tangents for the flexural load in the fastening points. In this case no torque is exerted on the fastening locations.

The anchoring member of the fastening member may be realized as an anchor body having, for example, the form of a pin having an undercut member which is arranged at the end of the anchor body opposite the back side of the element and which is displaceable and self-resetting.

The undercut member may, for example, be realized in the form of at least one snap-in locking member or of a snap-in hook. Alternatively the material of the anchoring member may also be elastic so as to expand again and thus reach around the undercut after having overcome a narrow passage in a reception on the transverse rail.

Various embodiments of the invention also provide panel-type elements, in particular panel-type facade elements, thermoelectric generator elements, thermal solar collectors, photovoltaic modules or solar modules having a back side to which a mounting system in accordance with the invention is fastened.

Embodiments of the invention further provide a substructure for forming a mounting plane and for holding at least one panel-type element having a mounting system in accordance with embodiments of the invention fastened to its back side in the mounting plane.

A substructure in accordance with various embodiments of the invention comprises at least one first and one second transverse rail which are arranged in parallel with and at a spacing from one another for holding at least one element. Each of the transverse rails has planar support surfaces at least in upper and a lower bearing locations of the at least one element. At least the first transverse rail, which is arranged above the second transverse rail relative to a line of slope of the mounting plane, comprises at least on the upper bearing locations recesses having undercuts for receiving the anchoring member and for cooperating with the undercut member of the anchoring member, in particular one having the form of at least one snap-in hook.

For the advantageous development of the mounting system, at least the second transverse rail comprises, at least in the area of lower bearing locations when viewed from the mounting plane, an undercut for a securing member fastened to the element.

If the element does not comprise an elastic member on its back side at the lower bearing locations, an elastic member, preferably of a silicone rubber, may alternatively or also additionally be arranged on the support surface of the second transverse rail as a bearing surface for the back side of the element. Such an elastic buffer member may also be fastened by means of an adhesive bond. Alternatively, in particular when the first and second transverse rails are substantially identical, such an element may also be anchored in a form-fit at the recesses that are provided in the case of use as a first transverse rail for the connection to a fastening member.

At least the first transverse rail may be realized as a profile rail, in particular with a C profile, having a groove in the plane of support. The groove then forms the recess for the fastening member and comprises at least the undercut for the displaceable undercut member.

In order to form the undercut for a securing member, at least the second transverse rail may have a flange plate extending along the transverse rail and in parallel with the mounting plane when viewed from the mounting plane. The profile of the transverse rail may also be realized symmetrically, i.e. comprise the flange plate on both sides when viewed from the mounting plane, so as to avoid erroneous mounting. Alternatively the undercut may also be constituted by the back side of the second transverse rail when viewed from the mounting plane. It should be evident that the securing member merely has to be adapted in the mouth opening width to the kind or shape of the undercut.

In the most simple case, the first and second transverse rails are realized as profile rails, in particular extruded profile rails, and preferably consist of a metal or a metal alloy, in particular aluminum or an aluminum alloy.

Some embodiments of the invention are particularly suited for fastening panel-type facade elements, thermoelectric generator elements, thermal solar collectors, photovoltaic modules and particularly in the case of frameless photovoltaic modules, as the fastening in accordance with embodiments of the invention advantageously avoids stresses in the panel-type element, in particular in rigid constituent parts such glass sheets or silicon layers of the element, due to wind load or snow load and thermal loads.

### BRIEF DESCRIPTION OF THE DRAWINGS

Further advantageous aspects of the invention as well as practical examples shall be explained in more detail below in connection with the attached figures of the drawings. Component parts or components having similar functions are partly provided with identical reference symbols. The expressions “left”, “right”, “top”, “bottom” as used within the description of the practical example refer to the figures of the drawings in an orientation in which the designation of the figure and reference symbols can be read in a normal fashion.

FIG. 1 shows a lateral view of panel-type PV modules fastened on a supporting structure and comprising a fastening system in accordance with an embodiment of the invention,

FIG. 2 shows a top view of the PV modules of FIG. 1,

FIG. 3 is a perspective representation of a PV module with a representation of the bearing forces in the fastening locations in a plane of projection,

FIG. 4a shows a lateral view of a PV module having fastening means in accordance with an embodiment of the invention, which interact with transverse rails of a substructure,

FIG. 4b shows a lateral view of a PV module having fastening means in accordance with another embodiment of the invention, which interact with transverse rails of a substructure, and

FIGS. 5a to 5c illustrate steps of the mounting operation of a PV module having fastening means in accordance with FIG. 4a on two transverse rails.

### DESCRIPTION

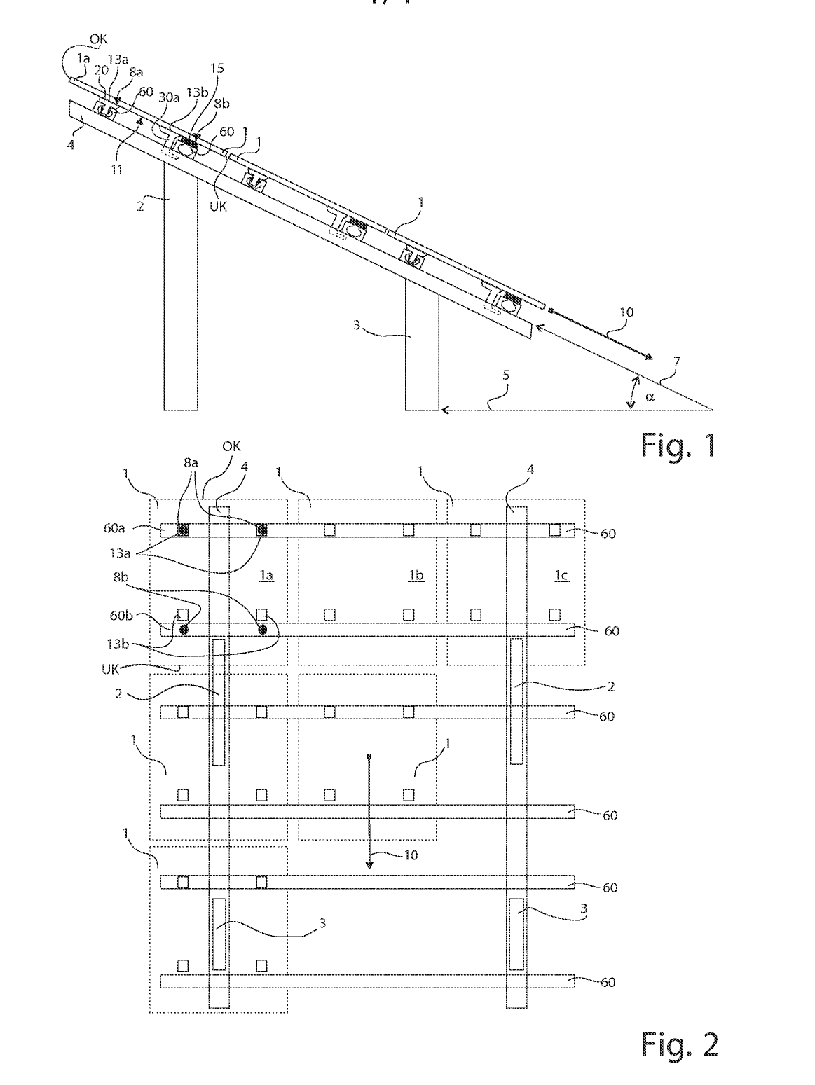

FIG. 1 and FIG. 2 schematically show the fastening and securing system or mounting system of the invention on the example of a field of PV modules having a plurality of panel-type PV modules arranged on a substructure or supporting structure as an example of panel-type elements within the meaning of the invention. The field of PV modules in the practical example is made up of nine panel-type solar modules or PV modules 1 of identical build. By way of example, the PV modules may be frameless panel-type thin-film modules of a rectangular format. The fastening system of the invention is fundamentally also suited for other kinds of panel-type elements, such as the facade elements as already mentioned in the foregoing, thermoelectric generator elements, thermal solar collectors, and the like.

It should be noted that for the purposes of a simplified representation, only six of the altogether nine mountable PV modules 1 are represented in the mounted condition in FIG. 2. In other words, three more PV modules 1 may be fastened to the substructure. Moreover reference symbols were omitted for reasons of clarity in cases of repeatedly occurring elements that might be designated by the same reference symbols. In FIG. 1 and FIG. 2 merely the PV module 1a is therefore provided with a reference symbol in detail.

The PV modules 1 are arranged obliquely on the substructure at an angle a that is customarily optimized with regard to the angle of insolation at the installation site. The substructure comprises two long props 2 and two short props 3 as well as two oblique beams 4, with each one of the oblique beams 4 being arranged obliquely at the angle a relative to the horizontal plane 5 by means of one of the long props 2 and one of the short props 3. The two oblique beams 4 form, jointly with transverse rails 60 arranged on them, a mounting plane 7 that is equally inclined at an angle a of, say, 30 degrees relative to the horizontal plane 5.

In FIG. 1 the mounting plane 7 is parallel with a module plane defined by the panel-type PV modules 1. In the mounting plane or module plane on the substructure, a PV module 1 is thus equally arranged at the angle a relative to the horizontal plane 5. By correspondingly dimensioning the fastening members still to be discussed in further detail and/or particular transverse rails 60, the very PV modules 1 may be arranged on the substructure at a particular angle with the mounting plane 7.

The arrow 10 in FIGS. 1 through 3 illustrates the slope descending direction or line of slope of the PV modules 1. The line of slope in the case of the panel-type modules is a line on the surface following the direction of the highest gradient; i.e., the line of slope would always intersect level indication lines entered on the module at a right angle.

In the practical example represented in FIGS. 1 and 2, the transverse rails 60 of the substructure are profile rails of identical build and substantially arranged in parallel with each other and with the two oblique beam 4 extending transversely on the latter. Two respective adjacent transverse rails 60 each carry three PV modules 1 arranged in a row; for instance, on the two topmost transverse rails 60 the PV modules 1a, 1b, 1c are supported on a first-upper-transverse rail 60a and a second-lower-transverse rail 60b.

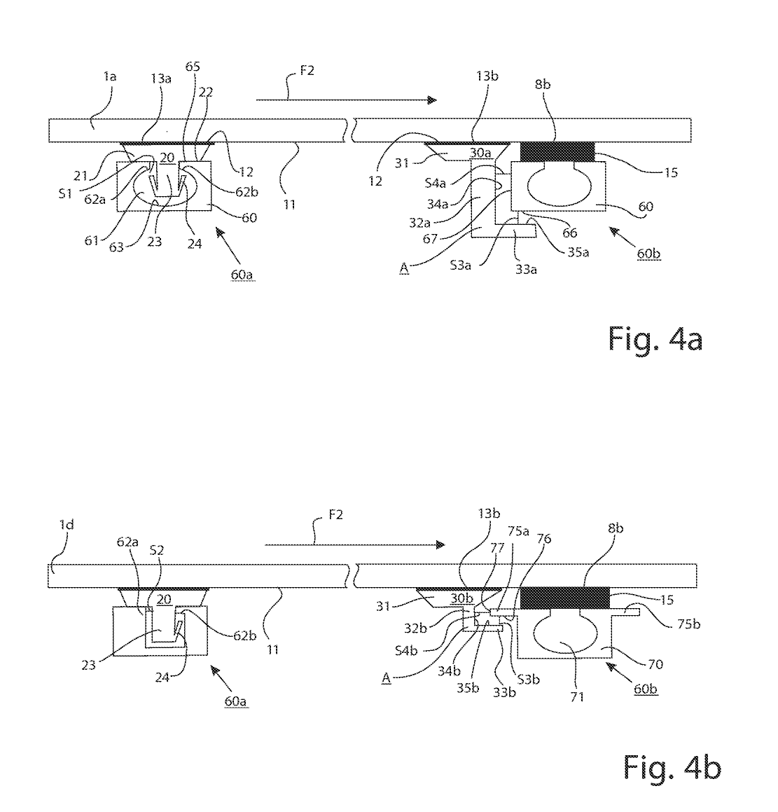

In the represented practical example, the transverse rails 60 have a cross-section in the form of a so-called C profile, with the cross-section being uniform across the entire length. The profile of the transverse rails 60 is represented more clearly in FIG. 4a.

The fastening system in accordance with embodiments of the present invention includes the transverse rails 60 to the extent that the profile of the transverse rails 60 is configured, at least in the area of the bearing points of the PV modules 1, such that a PV module 1 having fastening members configured in accordance with embodiments of the invention may cooperate with the transverse rail 60 in the respective bearing point in accordance with its purpose, i.e., it may be anchored thereon. It should therefore be evident that the profiles of the transverse rails 60 represented in the figures for illustration purposes merely represent an example, with the invention certainly not being limited to the concrete embodiment of a C profile.

It should furthermore be noted that it is also possible to arrange the transverse rails 60 of the substructure on the casing of a building, in particular on a facade or a roof of the building. When the PV modules are installed on an inclined roof, it may also be sufficient in the case of a suitable roof pitch to mount required transverse rails directly on the roof, in a given case by means of spacers. For the functioning of the mounting system still to be explained, the transverse rails 60 should extend, as represented, substantially transversely to the line of slope 10 of the PV modules 1.

FIGS. 1 and 2 further show that each panel-type PV module 1 is mounted on at least four points or locations on two respective ones of the transverse rails 60, with two each of the bearing points being provided as upper bearing points 8a or as lower bearing points 8b on each of the two transverse rails 60. In FIG. 2 the bearing points 8a, 8b are only represented in a simplified manner in connection with the PV module la. All of the bearing points 8a, 8b absorb the perpendicular forces engendered by the PV module that may be caused by the weight force, and in a given case additional loads such as due to wind or snow. The upper bearing points 8a additionally absorb the component of these forces that is directed along the line of slope 10.

As is furthermore explained in detail by referring to FIGS. 4a and 4b, fastening members 20 and securing members 30a and 30b fixedly connected to the PV module 1—for example by means of an adhesive layer 12 of suitable adhesive or a section of a two-sided adhesive tape—are provided on the back side 11 of each PV module 1 in the area of the upper bearing points 8a and in the area of the lower bearing points 8b, respectively.

The fastening members 20 or securing members 30a, 30b may already be fastened on the back side of the PV modules 1 at the manufacturer's site in the course of an industrial manufacturing process. Alternatively it is possible to repeatably fasten these elements at the installation site of the PV modules 1—for example by using a mounting template on locations on the respective PV module 1 that may be determined with the aid of the template, and thus in predetermined locations.

At any rate the fastening members 20 or securing members 30a, 30b are fixedly connected on the fastening surface 13 to the planar back side 11 of the PV module 1 by means of the adhesive layer 12. The adhesive layer 12 is discernible schematically, e.g. in FIGS. 4a and 4b between the back side 11 of the PV module 1 and the fastening member 20 or the securing member 30.

The fastening members 20 or securing members 30a, 30b may consist of a metallic material, for example of aluminum or an aluminum alloy, or alternatively of a plastic material. The back side 11 of a PV module 1 having the form of a frameless thin-film module usually consists of glass. Therefore, for example a component silicone adhesive having found acceptance for outdoor use is suited for bonding this combination of materials. Such an adhesive furthermore has a damping and compensating effect with a view to avoiding stresses in the PV module 1.

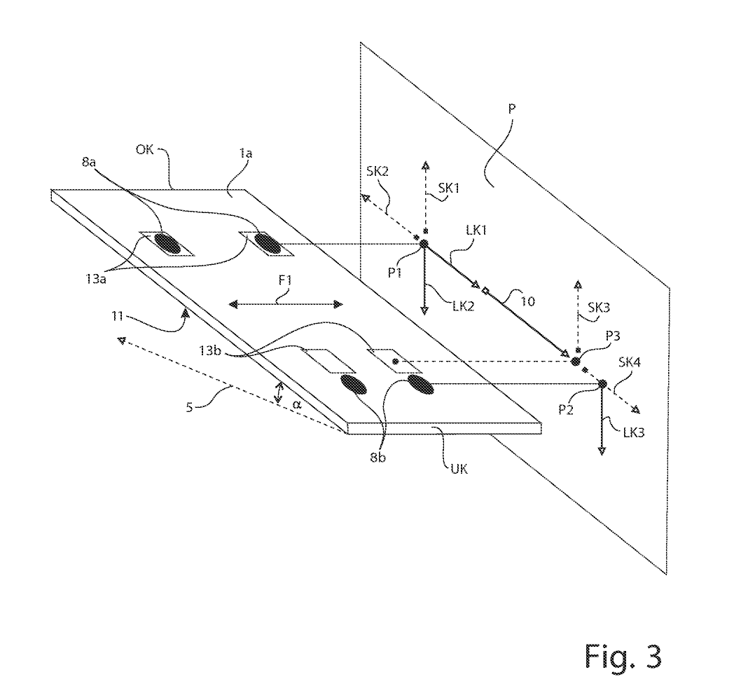

FIG. 3 shows a perspective representation of the PV module 1a with four fastening surfaces 13a of the fastening members 20 or fastening surfaces 13b of the securing members 30a and 30b, which are indicated schematically on the back side 11. Moreover the upper bearing points 8a and the lower bearing points 8b are indicated. For an illustration of the bearing forces or securing bearing forces occurring in the case of securing, corresponding force arrows are represented in the plane of projection P indicated to the right of the PV module 1.

The representation in the plane of projection P shows that in a case of a three-dimensional load on the panel-type PV module 1, the interaction of one respective upper bearing points 8a realized by means of a fastening member 20 with a lower bearing point 8b is of crucial importance with regard to the function of the fastening in accordance with embodiments of the invention. In the plane of projection P the function of the fastening and bearing in accordance with embodiments of the invention of the PV module 1 is reduced to a two-dimensional representation and thus substantially corresponds to the lateral views of FIGS. 4a and 4b.

In the plane of projection P the bearing forces LK1, LK2, LK3 occurring in the bearing points L1 and L2 are represented. The bearing forces LK2, LK3 correspond to the perpendicular forces of the PV module 1a introduced perpendicularly into the bearing points. The bearing force LK2 corresponds to the proportion of the weight force and of forces acting on the PV module that takes effect in the direction of the line of slope 10. In the upper fastening location this bearing force LK1 is absorbed by the anchoring member of the fastening means 20 which has to be explained in more detail in connection with FIG. 4a.

In the plane of projection P, securing forces SK1 to SK4 are furthermore entered which are represented at a distance from the respective projection point in the plane of projection. The distance illustrates a respective predetermined bearing play on the fastening member 20 or on the securing member 30a, i.e., the PV module 1a may be moved by a certain distance in the direction of the respective arrow of the securing forces before respective forces must or can be absorbed by the fastening member 20 or securing member 30a.

As was already mention, the bearing play for instance with regard to the force SK3 may be influenced by corresponding dimensioning of the mouth opening width of the securing member 30a. Merely with regard to the forces SK2 and SK4 a sufficient total play should be ensured in order to leave the PV module with sufficient “freedom of movement”, so that fluctuations of temperature may not cause thermal stresses in the PV module.

As a result of these freedoms of movement in the direction of the securing forces SK1 to SK4 as represented in FIG. 3, overdetermination or clamping of the support of the PV module 1a on the transverse rails 60 is avoided. Stresses in the PV module on account of the fastening are accordingly avoided.

In FIG. 3 it is well visible that in the direction of the arrow F1 the PV module is held in the bearing points solely by the static friction. Forces occurring in the PV module 1a in the direction of the arrow F1 can thus not result in stresses in the PV module 1a.

At corresponding dimensioning of the respective bearing play on the fastening means 20 or of the securing play on the securing means 30a, forces may furthermore be absorbed immediately. Here it is advantageous if the respective bearing play is filled by means of a soft, compressible, in a given case springily elastic intermediate element in order to still obtain sufficient freedom of movement by way of the elasticity in order to compensate tolerances and particularly load fluctuations occurring during operation, for example due to wind, snow etc. and/or material expansion or material shrinkage due to varying thermal loads. Oscillation or flutter of the PV module 1a on the transverse rails due to wind lift under unfavorable wind conditions may hereby be suppressed.

Intermediate elements appropriate for this purpose might, for instance, be produced of an elastic material such as a silicone-based elastomer (e.g. silicone rubber) or even soft plastic material, for example by direct spray-molding on the corresponding locations of the fastening members 20 or securing members 30a, 30b.

The bearing forces occurring in the normal load case, i.e. in the installed position with the PV module 1a placed on the transverse rails 60, are plotted directly at the respective projection point P1, P2 or P3 as respective force introduction points in the module 1a.

The projection point P1 visualizes the forces in connection with the fastening means 20 that is connected to the back side 11 of the PV module 1a at the fastening surfaces 13a. In the installed position, the forces LK1 and LK2 are conducted by the fastening means into an upper transverse rail of the substructure. The projection point P2 visualizes the force LK3 conducted into the lower transverse rail of the substructure at the lower bearing point 8b when the PV module 1a is in the installed position. The projection point P3 visualizes the delay by a securing member 30a connected to the back side 11 of the PV module 1a on the fastening surface 13b. In other words, if the PV module 1a is lifted up, for example by wind lift, then the securing member catches the PV module 1a only after a certain distance, to then conduct the applied forces into the lower transverse rail. As was already discussed, damage to the PV module 1a as a result of flutter owing to wind lift may be avoided entirely by corresponding dimensioning of the securing play, e.g. by intermediate arrangement of an elastic member.

FIGS. 4a and 4b show a first and a second practical example of a fastening for a PV module 1a or 1d in accordance with embodiments of the invention.

The foot 21 of the fastening members 20, or the foot 31 of the securing members 30a and 30b, has a cross-section similar to a trapeze. The material thickness of the feet 21 and 31 continuously decreases toward the edges on account of the trapeze shape, with the longer side of the trapeze constituting the respective fastening surface 13a or 13b. Due to the taper, the rigidity of the foot 21 or 31 decreases toward the edge of the respective fastening surface 13a or 13b, whereby an abrupt change of the rigidity of the foot between loaded and non-loaded areas of the back side 14 of the PV module 1 is avoided. This reduces local concentration of stress in the loaded condition. In this regard it should be noted that the edges of the feet 21 and 31 may also be realized to be round or angular.

The representation in FIG. 4a is a lateral view of the PV module 1a of FIGS. 1, 2, and 3. It may be seen that a fastening member 20 is attached on the panel-shaped base body of the PV module 1a on the back side 11 thereof in the fastening location 13a by means of the adhesive layer 12.

On the foot 21 of the fastening member 20 an anchoring member having an anchor body 23 is present on a bearing surface 22 facing the fastening surface 13a. The anchor body 23 is configured such that it may be made to engage a groove 61 in an upper transverse rail 60a of the transverse rails 60 of a substructure.

As was already explained, the upper transverse rail 60a comprises to this end a C profile having a groove 61. The groove 61 substantially has a U-shaped basic shape with inwardly directed undercuts 62a and 62b on the two leg ends of the U shape, i.e., on the opening of the groove 61. For the function of the fastening means 20 at least one of the undercuts 62a and 62b on the U legs should be present. The bottom 63 of the groove 61 might basically also be realized in sections thereof to be downwardly open in the transverse rail 60 and thus perforated, for example as a drain for condensed water.

On the anchor body 23 on the end facing the bearing surface 22 at least one anchoring member having the form of a spreader member is provided which is presently realized as a snap-in hook 24. In the practical example of FIG. 4a, the anchoring member comprises two snap-in hooks 24 which yield to the undercuts 62a, 62b when the anchor body 23 is inserted into the groove 61, or which are deflected or compressed at the narrow passage formed by the undercuts 62a, 62b and spread out or spread apart again within the groove 61 after having passed the narrow passage, to thus reach around the undercuts 62a, 62b. In FIG. 4b only one undercut 62b is provided on the groove in the transverse rail 60a, so that accordingly only one snap-in hook 24 is formed on the anchor body 23 for reaching around the undercut 62b.

The anchoring member may basically be realized as a snap-lock connection or anchor or the like. For example, the anchoring member might also consist of a mushroom-shaped elastic and thus compressible material which is compressed during insertion into the groove 61 and then again expands inside the groove 61 to reach around the undercuts 62a, 62b in this way.

As a result, when the PV module 1a is mounted, the fastening member 20 forms with the upper transverse rail 60a a form-fit connection in the manner of a snap-lock connection which may thus be produced in a simple manner and may, depending on dimensioning, only released again destructively or only by applying high force, in a given case by means of a dedicated tool. The form-fit connection may be adapted as an effective protection against theft, as an attempt to remove the PV module 1a from the transverse rails will result in destruction of the PV module.

It is also possible to fixedly attach the anchoring member in the reception realized as a groove through a permanent adhesive bond by means of an elastic adhesion agent, such as a silicone-based adhesive. If the adhesion agent still possesses sufficient elasticity in the cured condition to allow for a sufficient bearing play, this serves to avoid stresses in the module in the direction of the connecting line of adjacent fastening members.

In FIGS. 4a and 4b the possible bearing plays S1 and S2 explained in connection with the forces SK1 and SK2 in FIG. 3 are furthermore designated, the dimensioning of which still allows to preserve a certain mobility of the module in order to avoid stresses in the installed position. It should be noted that the bearing play shown in the figures was drawn larger than necessary for better visibility.

Furthermore it may be seen that the fastening means 20 has a bearing surface 22 that extends around the anchor body 23 and is in contact with the support surface 65 on the transverse rail 60a in the installed position. This contact surface corresponds to the upper bearing points 8a. It is, of course, also possible to provide an elastic layer or element at the bearing surface 22 and/or the support surface 65 to thereby provide dampening for the upper bearing points 8a.

The practical examples of FIGS. 4a and 4b are furthermore different with regard to the securing member 30a or 30b and in the profile of the transverse rail 70.

The securing members 30a and 30b are adapted to cooperate with a lower transverse rail 60b such that the securing member 30a or 30b is capable of preventing the PV module from being lifted off the lower transverse rail 60b, for example by wind lift.

To this end the securing member 30a or 30b is shaped such that it may either reach around the entire transverse rail 60 (FIG. 4a) or an edge provided at the transverse rail 70 (FIG. 4b) and having the shape of a flange plate 75, for example. The transverse rail 70 differs from the transverse rail 60 merely in the laterally molded edge 75 symmetrically projecting in the represented example in a wing-like manner at the outer sides of the U legs of the groove 71.

Due to the symmetrical configuration, the transverse rail 60b does not have a preferred direction of installation, whereby erroneous installation is precluded. It should be evident that it is fundamentally sufficient to provide the molded edge 75 at the transverse rail 60b only on the side directed towards the upper transverse rail 60a.

In general it should be noted in this context that—as is shown in FIG. 4a—profile rails having an identical profile may be used as upper transverse rail 60a and lower transverse rail 60b. In this case the two transverse rails can not be confused at the installation site. Furthermore only one rail type needs to be kept in stock. In other words, in the practical example of FIG. 4b it would also be possible to utilize a transverse rail 70 instead of the transverse rail 60a.

It is furthermore self-evident that the spreader member of the fastening member as a general rule must be adapted to the shape of the groove in the transverse rail. The skilled person is aware that he may carry out numerous modifications with regard to the concrete configuration both of the groove and of the anchoring member without thereby departing from the principles of the invention.

With regard to the securing members 30a (FIG. 4a) and 30b (FIG. 4b) it should be noted that these are as a general rule realized as an angled arm A fastened at the back side 11 of the PV module 1, with the arm A forming with the back side of the module 11 a mouth-type opening directed in the direction of the line of slope 10 of the module. In the first practical example of FIG. 4a the mouth opening width of the opening is dimensioned such that the arm A can reach around the entire transverse rail 60, and in the second practical example of FIG. 4b the mouth opening width of the opening is dimensioned such that the arm A can reach around the flange plate 75 provided on the transverse rail 70.

The angled arm A of the securing member 30a or 30b substantially comprises a section 32a or 32b that is perpendicular and a section 33a or 33b that is parallel to the back side 11 of the PV module 1a or 1d. The perpendicular section 32a or 32b has a perpendicular arm surface 34a or 34b which in the installed position faces an outer surface 67 of the transverse rail and which, due to the bearing play S4a or S4b, can enter into contact with the outer surface 67 only during installation. For the dimensioning of the bearing play S4a or S4b the spacing between the upper transverse rail 60a and the lower transverse rail 60b as well as the spacing between the fastening members 20 and the securing members 30a or 30b on the PV module 1 is decisive.

The section 33a or 33b parallel to the back side 11 has a contact arm surface 35a or 35b which, in the absence of a bearing play S3a or S3b, is in contact with the transverse rail back side 66 in the installed position of the PV module.

In the first and second practical examples the arm A appears to have a shape comparable to a hook. The difference from a hook in the securing member 30a or 30b, however, resides in the fact that this hook is unloaded when used as intended. In other words, the PV module 1a or 1d is precisely not hung on the transverse rail 60 or 70 by means of this hook, because the presumed hook does not conduct any component of the weight force exerted by the module.

Depending on the dimensioning of the bearing plays S3a or S3b and S4a or S4b, the securing member 30a or 30b merely absorbs the forces SK3 or SK4 (cf. FIG. 3) via the mouth opening width immediately or at a delay in the case of securing, if the PV module 1a or 1d is lifted up or in case it slides down too far in the direction of the line of slope 10 during installation. In other words, the hook function would here represent an advantageous secondary function during installation.

In order to avoid rattling of the PV modules due to wind lift, for example under unfavorable wind conditions, it is also possible besides the dimensioning of the mouth opening width to provide an elastic material in the area of the tolerances S3a and S3b so that in the normal condition in which the back side 11 of the module rests against all of the supporting locations, the PV module is retained but may nevertheless yield in the direction of the elastic material and particularly in the direction of the arrow F2 (cf. FIG. 4a or 4b) when loaded. I.e., occurring forces up to a certain magnitude will then be intercepted and attenuated through the compression of the elastic material, whereby increasing vibrations of the system are avoided.

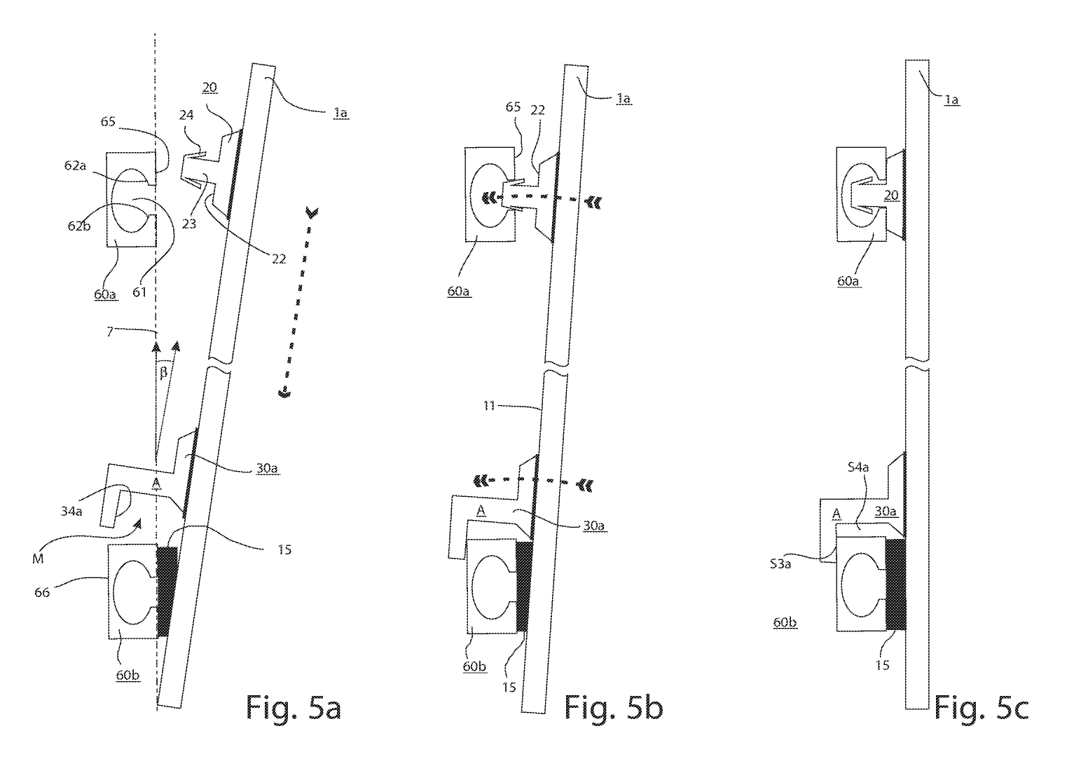

FIGS. 5a to 5c illustrate mounting of a PV module 1a of FIGS. 1 to 4a on two transverse rails 60 with the fastening and securing system of embodiments of the invention in accordance with the practical example of FIG. 4a. Here the bearing play S2a is equal to zero due to a corresponding dimensioning of the mouth width of the mouth-shaped opening formed by the angled arm A. The mobility of the PV module 1a in direction of the arrow F2 is ensured substantially by an elastic member 15 which is arranged between the lower transverse rail 60a and the back side 11 of the PV module 1a.

The elastic member 15 may, e.g., have a triangular, oval, circular or quadrangular cross-sectional shape as in FIGS. 5a to 5c. In the present practical example the elastic member 15 has a rectangular shape. In this case the plane of the cross-section extends at a right angle to the surface plane of the panel-type elements 1a and may extend such that the line of slope 10 (siehe FIG. 1) is contained in this cross-sectional plane. The elastic member 15 may be produced by cutting lengths of continuous material having a rectangular cross-section which is present in the form of an endless product.

The elastic member 15 may be made of a soft rubber, silicone, or ethylene propylene diene monomer rubber (EPDM). Soft rubber is a material which is particularly low-cost and easy to work. Silicone or ethylene propylene diene monomer rubber (EPDM) are particularly well suited because both materials are particularly UV-resistant. Moreover, silicone or ethylene propylene diene monomer rubber (EPDM) are particularly resistant to chemicals, in particular to ammonia-containing gases as may be present at elevated concentrations in the vicinity of agricultural buildings for livestock production.

The elastic member 15 is fastened integrally to the PV module 1a. When the elastic member 15 consists of silicone, the silicone may be spray-molded onto the PV module and thus provided with its desired shape. It is, however, also possible to use a pre-fabricated elastic member 15, e.g. of ethylene propylene diene monomer rubber (EPDM) for producing this integral connection, which is bonded onto a PV module.

Integral fastening of the elastic member 15 together with the fastening members 20 and the securing members 30a to the back side 11 of the PV module 1a or alternatively to the support surface of the transverse rail 60b integrally, for example by bonding, i.e. before the actual operation of mounting to the lower and upper transverse rails 60a, 60b, may basically already be carried out at the manufacturer's site.

FIG. 5a visualizes a first step of mounting the PV module 1a to the upper transverse rail 60a and the lower transverse rail 60b. To this end the PV module 1a is inserted on the lower transverse rail 60b by the opening M formed by the arm A of the securing member 30a. The PV module 1a should be moved with the opening M toward the transverse rail 60b from the direction of the upper transverse rail 60a, i.e. in the direction of the dashed single-point arrow, while forming an acute angle b with the mounting plane 7. As a result of the acute angle b the elastic member 15 is compressed between the transverse rail 60b and the back side 11 and thus advantageously dampens forces occurring during insertion of the PV module 1a.

FIG. 5b illustrates the following mounting step wherein, once the opening M reaches around the lower transverse rail 60b, the PV module 1a is tilted in the direction of the dashed double-point arrow, i.e. in the direction of the mounting plane 7. Tilting is performed in such a way that the anchor body 23 of the fastening member 20 is inserted into the groove 61 of the upper transverse rail 60a with the snap-in hook in front.

As is indicated in FIG. 5b, the snap-in hooks 24 are deflected inwardly, or pressed together, by the undercuts 62a and 62b at the opening of the groove 61 of the upper transverse rail 60a. Once the anchoring member constituted by the anchor body 23 and the snap-in hooks 24 has been inserted in the groove 61, the snap-in hooks again snap back into their original spread-apart position and thus reach around the undercuts 62a and 62b at the opening of the groove 61.

Now the installed condition shown in FIG. 5c has been established, in which the bearing surface 22 of the fastening member 20 rests against the support surface 65 of the upper transverse rail 60a. Furthermore the contact arm surface 34a of the securing member 30a contacts the back side of the lower transverse rail 60b, so that there is no bearing play S3a. Nevertheless the bearing play S4a in the direction of the line of slope 10 is adapted to be sufficiently large to compensate tolerances with regard to the distances of the mounted transverse rails 60 on the one hand and changing lengths of the PV module 1a due to fluctuations of temperature on the other hand.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A mounting system for panel-type elements, for fastening the element on at least one upper and one lower transverse rail which are arranged in parallel with and at a spacing from one another for holding an element,
the mounting system comprising:
at least one fastening member fixedly connected to the back side of the element, which comprises at least one anchoring member arranged substantially perpendicularly to the plane of the back side for fastening to the upper transverse rail,
wherein in the installed position of the element the fastening member has a smaller distance, relative to a line of slope, from an upper edge of an outer contour of the element than from a lower edge of the outer contour,
wherein at least one elastic member is arranged, relative to the line of slope, below the at least one fastening means on the back side of the element such that it rests on the lower transverse rail when an element is mounted on the transverse rails.

2. The mounting system according to claim 1,
wherein the mounting system further comprises at least one securing member which, in the installed position of the element, is arranged below the fastening member relative to the line of slope, and
wherein the securing member comprises an angled arm which extends at a spacing from and in parallel with the back side and substantially perpendicularly to the line of slope, which forms together with the back side a mouth-shaped opening opened substantially in the direction of the line of slope so as to reach around an undercut formed on or by the lower transverse rail when viewed from the mounting plane.

3. The mounting system according to claim 1,
wherein the at least one fastening member is fastened integrally to the back side of the element.

4. The mounting system according to claim 3, wherein the at least one fastening member is fastened integrally to the back side of the element using an adhesive bond.

5. The mounting system according to claim 2, wherein the at least one securing member is fastened integrally to the back side of the element.

6. The mounting system according to claim 1,
wherein a plurality of fastening members are arranged at the back side of the element on a line extending substantially perpendicularly to the line of slope.

7. The mounting system according to claim 2,
wherein a plurality of fastening members, and a plurality of securing members, are arranged at the back side of the element on a line extending substantially perpendicularly to the line of slope, and
wherein one respective fastening member and one respective securing member are arranged on the back side of the element on a line extending substantially in parallel with the line of slope.

8. The mounting system according to claim 7,
wherein the fastening member and/or the securing member are realized as profile rails each fastened to the back side of the element substantially perpendicularly to the line of slope.

9. The mounting system according to claim 1,
wherein the at least one fastening member or the at least one elastic member are each arranged inside the surface area of the back side at a distance from the outer contour of the PV-element, and in locations such that the element is subjected to a minimum flexural load in the installed position.

10. The mounting system according to claim 1,
wherein the anchoring member of the fastening member comprises an anchor body having an undercut member, in the form of at least one snap-in hook which is displaceable and self-resetting, arranged on an end of the anchor body opposite the back side of the element.

11. A panel-type element having a back side to which a mounting system according to claim 1 is fastened.

12. The element according to claim 11,
wherein the elements are photovoltaic modules.

13. A substructure for forming a mounting plane and for holding at least one panel-type element in the mounting plane in accordance with claim 11, wherein the substructure comprises:
at least one first and one second transverse rail which are arranged in parallel with and at a spacing from one another for holding at least one element,
wherein each one of the transverse rails comprises planar support surfaces at least in upper and lower bearing locations of the at least one element,
wherein at least the first transverse rail, which is arranged above the second transverse rail relative to a line of slope of the mounting plane, has, at least in the upper bearing locations recesses, undercuts for receiving the anchoring member and for cooperating with the displaceable undercut member having in particular the form of at least one snap-in hook,
wherein at least the second transverse rail comprises, at least in the area of lower bearing locations when viewed from the mounting plane, an undercut for a securing member fastened to the element, and in a preferred manner an elastic member is arranged on the support surface of the second transverse rail as a bearing surface for the back side of an element.

14. The substructure according to claim 13,
wherein at least the first transverse rail is a profile rail having a groove in the plane of support, wherein the groove forms the recess for the fastening member and comprises at least the undercut for the displaceable undercut member.

15. The substructure according to claim 13,
wherein at least the second transverse rail comprises a flange plate extending in parallel with the transverse rail so as to form the undercut.

16. The substructure according to claim 13,
wherein the first and second transverse rails are profile rails.

17. The substructure according to claim 16,
wherein the first and second transverse rails are extruded profile rails, consisting of a metal or a metal alloy.

18. The substructure according to claim 17,
wherein the metal or metal alloy comprises aluminum or an aluminum alloy.
